(19) United States
(12) Patent Application Publication
(10) Pub. No.: US 2026/0187296 A1
(43) Pub. Date: Jul. 2, 2026

(54) Computer-implemented method for providing a visual representation of the target and actual states of construction elements during construction

(71) Applicant: PERI SE, Weissenhorn (DE)

(72) Inventors: Florian BOTZENHART, Weissenhorn (DE); Bruno TORRINHA, Weissenhorn (DE)

(73) Assignee: PERI SE, Weissenhorn (DE)

(21) Appl. No.: 18/855,730

(22) PCT Filed: Mar. 29, 2023
(86) PCT No.: PCT/EP2023/058154

§ 371 Date: Oct. 10, 2024

(30) Foreign Application Priority Data
Apr. 11, 2022 (DE) 10 2022 108 800.6

(51) Int. Cl. G06F 30/13; G06F 3/01

(52) U.S. Cl. CPC G06F 30/13; G06F 3/016

(57) ABSTRACT

A computer-implemented method for providing a visual representation of target and actual states of construction elements during construction, comprising: providing a digital model of a plurality of construction elements, wherein the digital model comprises target data for at least a portion of the plurality of construction elements; providing a plurality of construction elements each comprising at least one sensor element configured to detect actual data for the nominal data provided in the digital model; provision of actual data by at least one of the sensor elements of at least one construction element; output of a visual representation of the actual and nominal data for at least one construction element by a visual output means in real time.

### FIELD OF THE INVENTION

The present invention relates to a computer-implemented method for providing a visual representation of target and actual states of construction elements during construction, a system for providing a visual representation of target and actual states of construction elements during construction, a corresponding computer program element and the use of a digital model, a plurality of construction elements and/or a visual output means in such a method.

### BACKGROUND OF THE INVENTION

Various systems for visualizing force flows are known from the prior art. For example, WO 2021/083796 A1 describes a system designed to determine and visualize force flows in a scaffold.

It has now become apparent that there is a need to provide a method and/or system that can be used to support a construction worker in the construction process.

In view of this, it is an object of the present invention to provide a method and/or a system that can be used to support a person carrying out construction work in the execution of the construction work. This and other objects, which will be mentioned in the course of reading the following description or can be recognized by a person skilled in the art, are achieved by the subject matter of the independent claims. The dependent claims further develop the central idea of the present invention in a particularly advantageous way.

### SUMMARY OF THE INVENTION

A first aspect of the present invention relates to a computer-implemented method for providing a visual representation of target and actual states of construction elements during construction, comprising:
providing a digital model of a plurality of construction elements, wherein the digital model comprises target data for at least a portion of the plurality of construction elements;
providing a plurality of construction elements, each comprising at least one sensor element configured to collect actual data on the target data provided in the digital model;
providing actual data from at least one of the sensor elements of at least one construction element;
outputting a visual representation of the actual and target data for at least one construction element by a visual output means in real time.

In other words, the present invention proposes to provide construction elements with one or more sensors and to record these as actual sensor data so that these actual sensor data can be compared with corresponding nominal data of a digital model. These comparison data can then be transmitted in real time to a construction worker, who can immediately check whether the construction work is or was carried out as planned.

The term “construction elements” is to be understood broadly and includes all elements that can be used in a construction. The present invention is not limited to the use of the same construction elements or the same sensor elements and also includes the use of different construction elements or different sensor elements. For example, the construction element can be a formwork element, a supporting element, a carrier element, a scaffolding element, etc.

The term “digital model” is to be broadly understood in the present case and includes any computer-based “virtual” model that can be used to assign target data to the plurality of construction elements. In practice, this is a planning tool in which the positioning of a construction element, the installation location, the type of fastening, a force distribution, a force absorption, etc. can be recorded as target data. In one example, a digital twin of the multitude of construction elements planned for a construction project is created using such a planning tool. The digital model can be limited to the construction elements or can also include representations of the facilities surrounding the construction elements, such as ceilings, walls, doors, etc.

The term “sensor element” is to be broadly understood in the present case and includes any sensor element that can be arranged in a construction element or can also be assigned to such a construction element. Preferably, the sensor elements are provided directly on or in the construction element. Alternatively, however, it is also possible to provide a sensor element, for example a temperature sensor, separately from the construction element.

The term “actual and target data” is to be understood broadly in the present case and includes each “data pair” that can be compared with each other or that can be visually represented by the visual output means. The present invention is also not limited to a specific data format. It may also be possible that the sensor data is provided as analog data, which is then converted into digital data by means of an A/D converter, i.e. possible data processing steps that are to be carried out in order to be able to display the actual and target data are also included.

The term “visual display” is to be broadly understood in this case and includes every display alternative through which the actual and target data can be displayed. These can, for example, be displayed as two separate bar displays so that the actual and target data can be directly compared. Alternatively, the actual and target data can also be displayed in a combined view, for example as a bar chart that varies in color according to the deviation of actual and target data. Alternatively or additionally, a linked representation can be used. For example, a bar display with an indicator, such as an arrow indicator, allows a comparison of actual and target data. Alternatively or in addition, a linked representation can be used. For example, a bar chart with an indicator, such as an arrow indicator, allows a comparison of actual and target data. Such a representation facilitates orientation for a person carrying out the work and allows for easier construction.

The term “visual output device” is to be broadly understood in the present case and includes any visual output device that is suitable for visually displaying the actual and target data or a comparison of the actual and target data. For example, data glasses, helmet visors, lenses, HUD elements, holographic elements, etc. can be used in the present case.

The term “real time” is to be broadly understood in the present case and can be understood differently depending on the application, sensor type, etc. Preferably, the term “real time” is to be understood as less than 1 s, particularly preferably less than 0.5 s. In other words, it is preferred that a change in the actual data during construction be displayed by the visual output means within a period of less than 1 s or less than 0.5 s. In alternative applications, larger time intervals can still be considered real-time if, based on experience, the sensor value has a slower rate of change, as may be the case with temperature sensors, for example. It may also be envisaged that different real-time requirements are defined depending on the sensor element, i.e. that different data transmission intervals can be defined for different sensor types. For example, shorter data transmission intervals can be defined for temperature sensors, since experience shows that this sensor value changes only slowly. Whereas for construction elements, such as scaffolding elements, which are to be correctly positioned or operated according to the nominal data, lower data transmission intervals can be provided. In one example, the respective data transmission intervals for the sensor elements are already taken into account when planning the digital model or are included in it as control data.

In one embodiment, the digital model is a three-dimensional model of at least a part of a structure to be constructed, in which the plurality of construction elements are included. The use of such a “realistic” or “more realistic” three-dimensional model can significantly facilitate the planning of the digital model, since it provides the user with a direct reference to reality. For optimized planning and construction, the digital model can be digitally recorded or provided with a variety of relevant (building) data. In addition, trade-specific information/data can also be included.

In one embodiment, the construction element is a formwork element, a supporting element, a carrier element and/or a scaffolding element. In another example of a construction element, this can be a frame of a building 3D printer, for example to represent an intended positioning of such a frame and/or the respective intended load bearing of such a support by means of the actual and target data. Such a building 3D printer comprises a frame/column, preferably four or more such frames.

In one embodiment, the nominal and actual data relate to operating data of the construction elements, pressure data, position data, load data, position data and/or type data of the respective construction element.

In one embodiment, the at least one sensor element of a construction element is a position sensor, force sensor, pressure sensor, angle sensor, a strain gauge (DMS), a distance sensor, a humidity sensor, a gyroscope, in particular a MEMS gyroscope or a concrete pressure sensor.

In one embodiment, the visual output means is designed as a mobile visual output means and as an extended reality (XR) unit (for example as a virtual reality (VR) and/or as an augmented reality (AR) unit).

In one embodiment, the visual output means is a pair of data glasses, a helmet with a head-up display, a holographic element or a mobile computing unit such as a smartphone, tablet, laptop, etc. In this case, mobile devices and XR devices are typically used for applications on construction sites and laptops are typically used for remote access, possibly as an office integration.

In one embodiment, output of the visual representation of the actual and nominal data is triggered by positional data from the mobile visual output device. Preferably, this triggers a visual representation of the actual and nominal data for at least some of the plurality of construction elements. The position data can be provided, for example, by a radio-based location determination, such as a Bluetooth location determination, or also by a GPS unit. Alternatively or additionally, the position data can also be provided by means of a laser measuring device, a camera-based position determination or similar.

In one embodiment, the method further comprises providing a haptic feedback means that is configured to output a haptic signal as a function of the actual and target data, wherein the haptic feedback means is particularly embodied as a wristband, glove or vibration insert. For example, such a vibration insert can be controlled in such a way that a stronger vibration signal is output when there is a greater deviation between the actual and target data.

In one embodiment, the method further comprises providing an acoustic feedback means that is configured to output an acoustic signal as a function of the actual and target data. For example, an acoustic signal can be output in such a way that a louder acoustic signal is output when the actual and target data deviate more.

In one embodiment, the method further comprises integrating a new construction element into the digital model, comprising the steps of:
providing a further construction element having at least one sensor element;
detecting the distances of the construction element to at least two neighboring construction elements;
integrating the further construction element into the digital model with respect to the closest construction element.

Another aspect of the present invention relates to a system for providing a visual representation of target and actual states of construction elements during construction, comprising:
a first provisioning unit configured to provide a digital model of a plurality of construction elements, wherein the digital model comprises target data for at least a portion of the plurality of construction elements;
a plurality of construction elements, each comprising at least one sensor element configured to collect actual data on the target data provided in the digital model;
a second provisioning unit configured to provide actual data from at least one of the sensor elements of at least one of the construction elements;
output of a visual representation of the actual and target data for at least one construction element by a visual output means in real time.

With respect to the respective elements, effects, terms and/or advantages, the explanations and descriptions regarding the methods described above for providing a visual representation of the target and actual states of construction elements during construction apply here. The explained embodiments can also be correspondingly used and provided in the present system for providing a visual representation of the target and actual states of construction elements during construction.

In one embodiment, the provision units, the visual output means and the sensor elements are directly or indirectly connected to each other via at least one communication node. Such a communication node can be provided, for example, by a local wireless network. In an example, the digital model or the corresponding data processing can be provided close to a construction site in a local construction site network. Respective data paths can be provided, for example, by WLAN, Bluetooth, LoRaWAN or the like. Alternatively or additionally, cloud connections, mobile connections, etc. can also be provided in order to be able to use non-locally provided resources alternatively or additionally. Such remote connections can be provided permanently or only temporarily.

Another aspect of the present invention relates to a computer program element comprising instructions that, when executed on computer devices of a computer environment, are configured to carry out the steps of the method explained above in a system explained.

Another aspect of the present invention relates to the use of a digital model, a plurality of design elements, and/or a visual output means in a method explained above.

### DESCRIPTION OF A PREFERRED EMBODIMENT

Further features, advantages and possible applications of the present invention will become apparent from the following description, the example and the figures. The following show

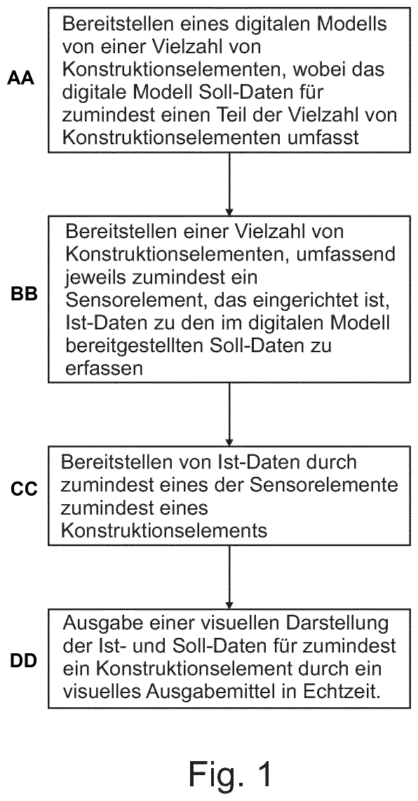

FIG. 1 a schematic illustration of the steps of a method according to the present invention;

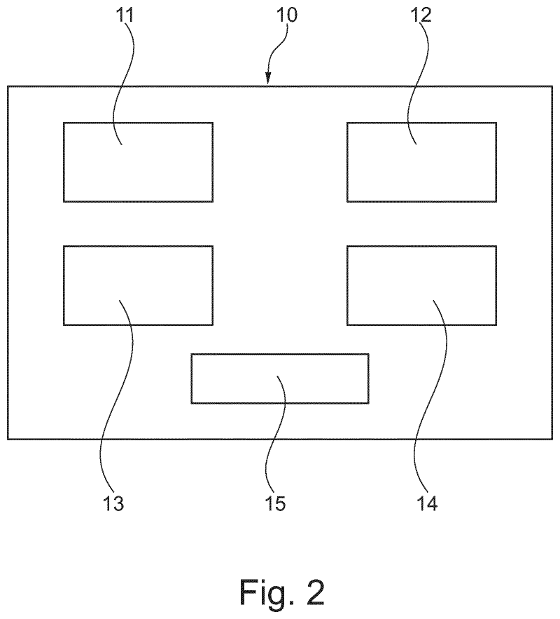

FIG. 2 a schematic view of a system according to the present invention;

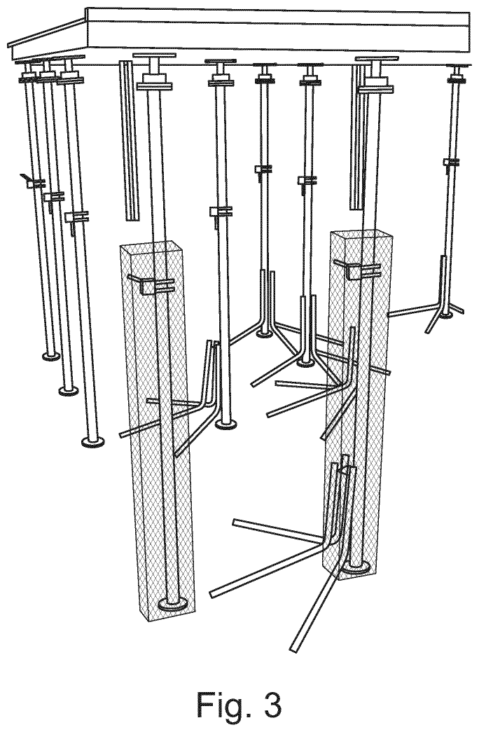

FIG. 3 a schematic view of a digital model;

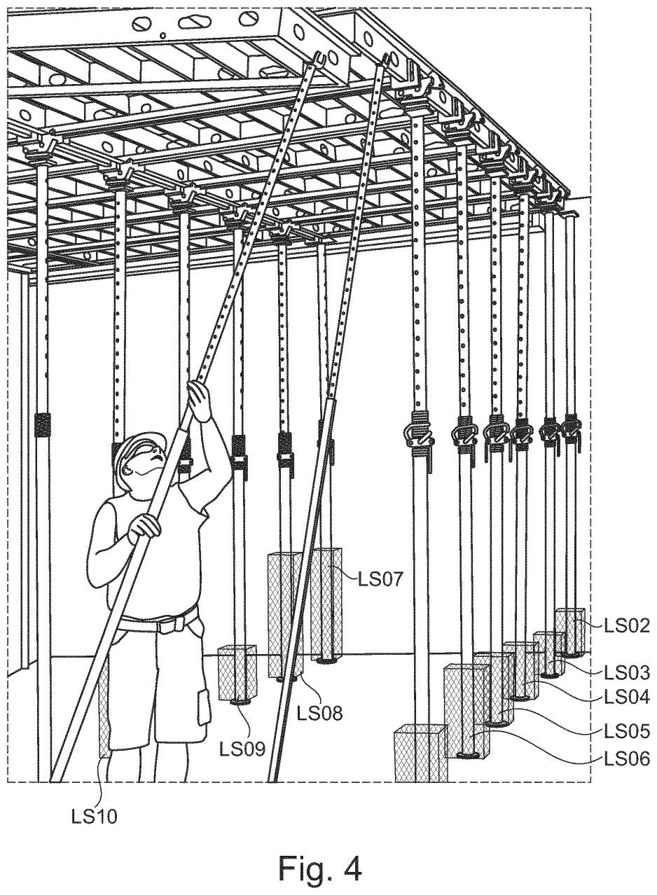

FIG. 4 a schematic view of a visual representation of actual and desired data; and

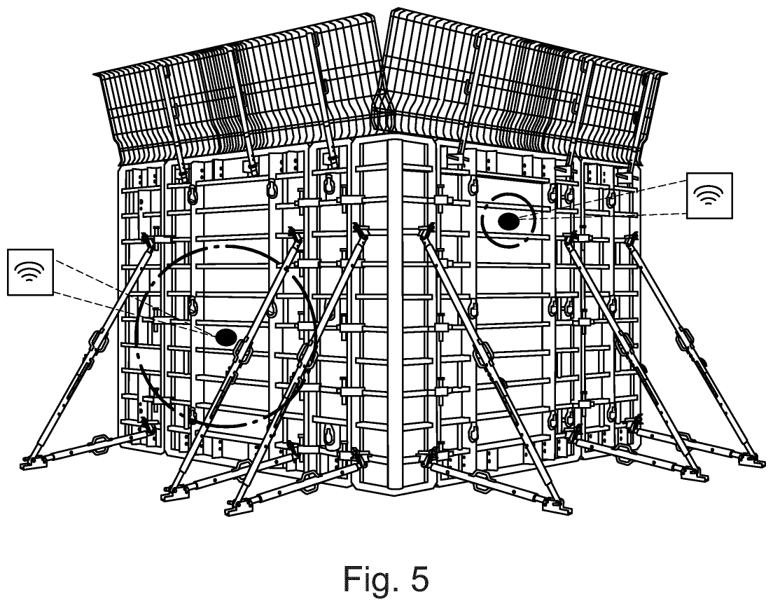

FIG. 5 a schematic view of a further example of a visual representation of actual and desired data.

FIG. 1 shows a schematic illustration of the steps of a method according to the present invention for providing a visual representation of nominal and actual states of construction elements during construction.

In a first step, a digital model of a plurality of construction elements is provided, wherein the digital model comprises nominal data for at least some of the plurality of construction elements.

In the preferred embodiment, such a digital model is a “realistic” digital model, as shown in FIG. 2 by way of example. In the exemplary digital model, the nominal data/values are visually assigned to a construction element, in this case a supporting element. In the illustration shown, the nominal data is introduced as a bar display. In the example shown, the target data is load-bearing data that can be recorded using a force sensor, for example.

In a second step, a large number of design elements are provided, each of which comprises at least one sensor element, here preferably at least one force sensor in each case. These sensor elements are configured to record actual data for the target data provided in the digital model.

In a further step, the actual data of the construction elements recorded by the sensor elements are provided and transmitted to or retrieved from a data point.

Finally, a visual representation of the actual and target data for at least one construction element is output in real time by a visual output means. Such an exemplary visualization, which can be provided, for example, in the context of an augmented reality application by data glasses, is shown in FIG. 3.

FIG. 4 shows an exemplary system 10 for providing a visual representation of target and actual states of construction elements during construction. The system comprises at least a first provisioning unit 11 configured to provide a digital model of a plurality of construction elements, wherein the digital model comprises target data for at least some of the plurality of construction elements; a plurality of construction elements 12, each comprising at least one sensor element 13 that is configured to sensing actual data related to the nominal data provided in the digital model; a second providing unit 14 configured to provide actual data of at least one of the sensor elements of at least one of the construction elements; visual output means 15 for outputting a visual representation of the actual and nominal data for at least one construction element in real time.

FIG. 5 shows a schematic view of a further example of a visual representation of actual and target data. A formwork arrangement with respective formwork elements is shown as the construction element. A plurality of pressure sensors are provided on or in the formwork elements and are configured in such a way as to detect the pressure acting on the respective surfaces. The measured/recorded pressure values represent the actual data, which are compared with the stored target data. In the example shown, a circular visual display is used to indicate a deviation or a comparison of the actual and target data/values. The display, here the dashed circle, can vary correspondingly in its size and/or its color. For example, the size of the circle can be used to show that the pressure is or will be either greater or smaller. The maximum load/pressure absorption can also be shown by means of a red highlighting/color, a minimum load can be shown, for example, by means of a green color and a small circle.

However, the present invention is not limited to the preceding preferred embodiments as long as it is comprised within the subject matter of the following claims.

In addition, it should be noted that the terms “comprising” and “having” do not exclude other elements or steps and the indefinite articles “a” or “an” do not exclude a plurality. Furthermore, the term “unit” is to be understood broadly; in particular, this term is not to be understood to mean that the respective units must be designed as integral components. The respective units can also be positioned differently. Finally, different units can also be combined in an assembly. Furthermore, it should be noted that features or steps described with reference to one of the above examples can also be used in combination with other features or steps of other examples described above.

1. A computer-implemented method for providing a visual representation of target and actual states of construction elements during construction, comprising:
providing a digital model of a plurality of construction elements, wherein the digital model comprises target data for at least a portion of the plurality of construction elements, wherein, during construction, there are a plurality of construction elements, each comprising at least one sensor element configured to collect actual data on the target data provided in the digital model;
providing actual data from at least one of the sensor elements of at least one construction element; and
outputting a visual representation of the actual and target data for at least one construction element by a visual output device in real time.

2. The computer-implemented method according to claim 1, wherein the digital model comprises a three-dimensional model of at least part of a structure to be constructed and the plurality of construction elements.

3. The computer-implemented method according to claim 1, wherein the construction element is a formwork element, a supporting element, a carrier element and/or a scaffolding element.

4. The computer-implemented method according to claim 1, wherein the nominal and actual data relate to operating data of the construction elements, pressure data, position data, load data, position data and/or type data of the respective construction element.

5. The computer-implemented method according to claim 1, wherein the at least one sensor element of a construction element is a position sensor, force sensor, pressure sensor, angle sensor, a strain gauge, a distance sensor, a humidity sensor, a gyroscope, in particular a MEMS gyroscope or a concrete pressure sensor.

6. The computer-implemented method according to claim 1, wherein the visual output device is one or more of an extended reality (XR) unit, a virtual reality (VR) unit, and/or an augmented reality (AR) unit.

7. The computer-implemented method according to claim 1, wherein the visual output devices is one or more of: a pair of data glasses, a helmet with a head-up display, a holographic element or a mobile computer unit.

8. The computer-implemented method according to claim 1, wherein an output of the visual representation of the actual and desired data is triggered by positional data of the visual output device mobile visual output means, and triggers a visual representation of the actual and desired data for at least some of the plurality of construction elements.

9. The computer-implemented method according to claim 1, further comprising:
providing a haptic signal to a haptic feedback device based on the actual and target data, wherein the haptic feedback device is a wristband, glove or vibration insert.

10. The computer-implemented method according to claim 1, further comprising
providing an acoustic signal to an acoustic feedback device based on the actual and nominal data.

11. The computer-implemented method according to claim 1, wherein there is a further construction element having at least one sensor element, and the method further comprises integrating a new construction element into the digital model by:
determining the distances of the further construction element to at least two neighboring construction elements; and
integrating the further construction element into the digital model with respect to the closest construction element.

12. A system for providing a visual representation of nominal and actual conditions of construction elements during construction, comprising:
a first provisioning unit configured to provide a digital model of a plurality of construction elements, wherein the digital model comprises target data for at least some of the plurality of construction elements;
a plurality of construction elements, each comprising at least one sensor element configured to collect actual data on the target data provided in the digital model;
a second provisioning unit configured to provide actual data from at least one of the sensor elements to at least one of the construction elements;
at least one visual output device for outputting a visual representation of the actual and target data for at least one construction element in real time.

13. The system according to claim 12, wherein the provisioning units, the visual output device and the sensor elements are directly or indirectly connected to one another via at least one communication node.

14. A computer program element comprising instructions configured, when executed on computer equipment in a computing environment, to perform operations comprising:
initializing a digital model of a plurality of construction elements, wherein the digital model comprises target data for at least a portion of the plurality of construction elements;
receiving actual data corresponding to the target data, the actual data being derived from at least one sensor coupled to each of a plurality of construction elements during construction of a structure; and
outputting, in real time by a visual output device, a visual representation of the actual and target data for at least one construction element of the plurality of construction elements.

15. (canceled)
